(19) United States
(12) Patent Application Publication
(10) Pub. No.: US 2026/0230089 A1
(43) Pub. Date: Aug. 6, 2026

(54) PROCESSING UNIT CONFIGURED TO CONVERT THE DATA FORMAT OF DATA ELEMENT VALUES USING AN INTERMEDIATE DATA FORMAT

(71) Applicant: ADVANCED MICRO DEVICES, INC., Santa Clara, CA (US)

(72) Inventors: Eric Mark Schwarz, Fishkil, NY (US); Stuart David Simpson Biles, Bury St. Edmunds (GB); Michael Estlick, Fort Collins, CO (US)

(21) Appl. No.: 19/434,744

(22) Filed: Dec. 29, 2025

Related U.S. Application Data
(60) Provisional application No. 63/751,985, filed on Jan. 31, 2025.

(51) Int. Cl. H03M 7/24; G06F 9/50

(52) U.S. Cl. CPC H03M 7/24; G06F 9/5027

(57) ABSTRACT

To convert a value from an initial data format to a modified data format having a modified data format style, an accelerator unit executes a first instruction to convert the value from the initial data format to an intermediate data format in an intermediate data format style. The accelerator unit then rounds the value in the intermediate data format according to an intermediate rounding mode. After rounding the value, the accelerator unit executes a second instruction to convert the value to the modified data format in the modified data format style. Further, the accelerator unit rounds the value according to a modified rounding mode such that converting the value from the initial data format to the modified data format introduces a single rounding error.

### BACKGROUND

To implement certain machine-learning models for an application, a processing system includes specialized processing units, such as graphics processing units (GPUs), that perform tensor operations using values representing the weights and parameters of the machine-learning models. When implementing a machine-learning model, a specialized processor uses values in various data formats such that different tensor operations for the machine-learning model are performed at varying levels of precision, which increases the accuracy of results from some tensor operations while reducing the processing resources needed to perform other tensor operations. However, converting values between the data formats supported by the specialized processing unit increases the number of instructions that need to be executed by the specialized processing unit and increases the overall processing resources needed to implement a machine-learning model.

### BRIEF DESCRIPTION OF THE DRAWINGS

The present disclosure may be better understood, and its numerous features and advantages made apparent to those skilled in the art by referencing the accompanying drawings. The use of the same reference symbols in different drawings indicates similar or identical items.

FIG. 1 is a block diagram of a processing system supporting an instruction set configured to convert values used in tensor operations from a first data format to a second, less precise data format by using an intermediate data format, in accordance with embodiments.

FIG. 2 is a flow diagram of an example operation for converting the value of a data element from an original data format to an intermediate data format, in accordance with embodiments.

FIG. 3 is a flow diagram of an example operation for converting the value of a data element from an intermediate data format to a modified data format, in accordance with embodiments.

FIG. 4 is a flow diagram of an example operation for converting a value from a first data format to a second, less precise data format based on whether the value is denormalized, in accordance with embodiments.

FIG. 5 is a flow diagram of an example method for converting from a first data format to a second, less precise data format by using an intermediate data format, in accordance with embodiments.

### DETAILED DESCRIPTION

Systems and techniques disclosed herein include a processing system configured to perform one or more tensor operations for one or more applications. As an example, while executing certain applications, the processing system is configured to implement machine-learning models such as supervised machine-learning models, unsupervised machine-learning models, reinforcement machine-learning models, neural networks, deep-learning neural networks, large language models, multimedia large language models, and the like that are configured to generate data for the executing applications. These machine-learning models, for example, require the processing system to perform various tensor operations that use values representing the matrices representing weights, biases, scales, and the like of a corresponding machine-learning model. These tensor operations include, for example, one or more dot product operations (e.g., scaled dot product operations), addition operations, subtraction operations, inversion operations, division operations, multiplication operations, and the like. To perform these tensor operations for an application (e.g., for a machine-learning model implemented for the application), the processing system includes an accelerator unit (AU) having one or more processor cores that each operate as one or more compute units. A compute unit, for example, includes one or more single instruction, multiple data (SIMD) units having arithmetic logic unit (ALU) circuitry that includes one or more ALUs configured to perform tensor operations using data stored in vector registers included in or otherwise connected to the SIMD unit, hardware buffers of the AU, or both. As an example, when implementing a machine-learning model, an AU is configured to first perform one or more dot-product operations with matrices that include data elements storing values representing the weights, biases, scales, and the like of the machine-learning model to produce one or more result matrices. The AU then, for example, performs one or more tensor operations using values stored in elements of the result matrices so as to implement the machine-learning model.

In the processing system, the values representing the parameters (e.g., weights, biases, scales) of the machine-learning model are stored in a first high-precision data format, such as Floating Point (FP) 32, FP64, and the like. However, using a high-precision format when performing tensor operations that require less precision (e.g., tensor operations using values from result matrices) uses more processing resources than are needed to perform such tensor operations. As such, to reduce the processing resources needed to perform tensor operations requiring a lower precision, the AU is configured to convert values for tensor operations from a first data format to a second, less precise data format, such as FP6 or FP4, in one or more data format styles. These data format styles, for example, indicate how many bits of data in the data format are allocated to exponent bits of the value and how many bits of data in the data format are allocated to mantissa bits. As an example, the AU is configured to convert a value from a first data format (e.g., FP32) to FP6 in a E3M2 (e.g., 3 exponent bits, 2 mantissa bits) data format style, FP6 in a E2M3 (e.g., 2 exponent bits, 3 mantissa bits) data format style, FP4 in a E2M1 (e.g., 2 exponent bits, 1 mantissa bit) data format style, or any combination thereof. Additionally, the AU is configured to convert the value to the second data format such that the converted value is rounded according to a desired rounding mode, such as a round to nearest even (RNE) mode, round to odd (RTO) mode, stochastic rounding mode, or any combination thereof. For example, in response to receiving one or more instructions indicating that data is to be converted from a first data format (e.g., FP32) to a second data format (e.g., FP6 E3M2) using a RNE rounding mode, the AU converts the data from the first data format to the second format such that the value in the second data format was rounded based on a corresponding rounding mode.

To enable the AU to convert a value from a first data format to a second, less precise data format (e.g., a second data format having a desired data format style and rounded according to a desired rounding mode), the AU supports an instruction set (e.g., the AU has an instruction set architecture (ISA) configured to execute instructions from an instruction set) that includes a first group of instructions that convert values from a first data format (e.g., FP32) to a predetermined intermediate data format and a second group of instructions that convert values from the predetermined intermediate data format to a target data format (e.g., modified data format). As an example, to convert a value from a first data format (e.g., FP32) to a second data format (e.g., FP6) having a desired data format style (e.g., E3M2) and rounded according to a desired rounding mode (e.g., RNE), the AU first executes an instruction from the first group of instructions that converts the value to an intermediate data format (e.g., FP8) having a data format style and rounding mode based on the desired data format style and desired rounding mode for the second data format. That is to say, the AU executes an instruction that converts the value to an intermediate data format with a data format style (e.g., intermediate data format style) and rounded according to a rounding mode (e.g., intermediate rounding mode) that allow the value in the intermediate data format to be converted to the second data format with the desired data format style and desired rounding mode, for example, without introducing errors in the value, to achieve a threshold accuracy, or both. After converting the value to the intermediate data format in the intermediate data format style and rounding the value according to the intermediate rounding mode, the AU then executes an instruction from the second group of instructions that converts the value from the intermediate data format (e.g., with the intermediate data format style) to the second data format having the desired data format style and rounds the converted value according to the desired rounding mode. By executing the instruction from the second group of instructions, the AU produces the value in the desired data format style with only a single rounding error (e.g., a rounding error based on the desired rounding mode). That is to say, the AU produces a value in the desired data format style with the same degree of rounding error (e.g., a single rounding error) as if the value had been converted directly from the first data format to the desired data format.

Additionally, to prevent denormalized values (e.g., a number having a most significant mantissa bit of zero) from causing errors when converted to a second data format, the instruction set supported by the AU includes a third group of instructions that convert denormalized values from a first data format (e.g., FP32) to the intermediate data format with an intermediate data format style and intermediate rounding mode that allow the denormalized value to be converted to a second data format with a desired data format style and rounding mode. After executing an instruction from the third group of instructions to convert the denormalized value to the intermediate data format, the AU executes an instruction from the second group of instructions that converts that value from the intermediate data format to the second data format. For example, in response to determining that a value to be converted from a first data format (e.g., FP32) to a second data format (e.g., FP4, FP6) having a desired data format style and desired rounding mode is a denormalized value, the AU first executes an instruction from the third group of instructions that converts the denormalized value from the first data format to the intermediate data format in a corresponding intermediate data format style and rounds the converted denormalized value according to a corresponding intermediate rounding mode based on the desired rounding mode for the second data format. After converting the denormalized value to the intermediate data format, the AU executes an instruction from the second group of instructions that converts the denormalized value from the intermediate data format to the second data format with the desired data format style.

In this way, the AU is configured to support the conversion of values from a high-precision data format to a second, less precise data format by using an intermediate data format such that only a single rounding error is introduced. By first converting values to a predetermined intermediate data format and then converting the values in the intermediate data format to a second, less precise data format, the AU reduces the number of conversions needed to convert the values when compared to systems that support different instruction sets for converting values. Because the number of conversions is reduced, fewer instructions are needed to convert the values to the second data format, which reduces the hardware and processing resources needed to convert the values while still limiting the number of rounding errors introduced.

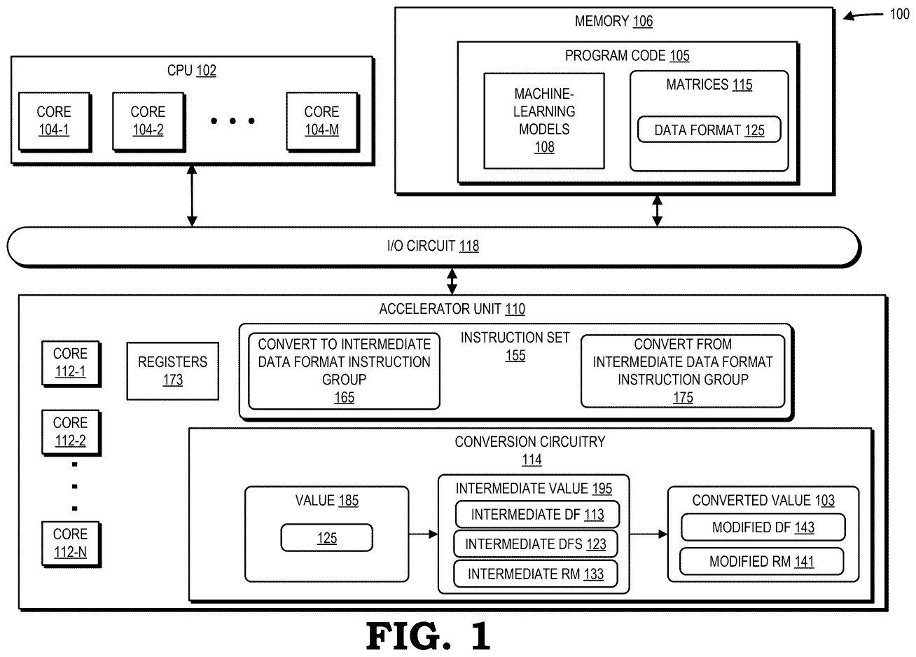

Referring now to FIG. 1, a processing system 100 configured to convert values used in tensor operations from a first data format to a second, less precise data format by using an intermediate data format is presented, in accordance with embodiments. According to implementations, processing system 100 is configured to execute one or more applications that require one or more tensor operations to be performed, such as dot product operations (e.g., scaled dot product operations), addition operations, subtraction operations, inversion operations, multiplication operations, division operations, and the like, using one or more values 185. As an example, processing system executes an application that requires processing system 100 to implement one or more machine-learning models 108, such as one or more supervised machine-learning models, unsupervised machine-learning models, reinforcement machine-learning models, neural networks, deep-learning neural networks, large language models, multimedia large language models, and the like. While implementing a machine-learning model 108, processing system 100 is configured to perform one or more tensor operations (e.g., dot product operations) using matrices 115 having elements that store values 185 representing the weights, biases, scales, or combination thereof of the machine-learning model 108. For example, processing system 100 performs one or more dot product operations using values from two or more matrices 115 to generate one or more result matrices. Processing system 100 then performs one or more additional tensor operations (e.g., additional operations, subtraction operations, multiplication operations, division operations, inversion operations, and the like) using one or more values 185 stored in the elements of the result matrices.

To perform tensor operations for an application (e.g., for a machine-learning model 108 implemented for an application), processing system 100 includes AU 110 configured to execute instructions so as to perform one or more tensor operations using one or more values 185. AU 110 is configured to operate as one or more vector processors, coprocessors, graphics processing units (GPUs), general-purpose GPUs (GPGPUs), non-scalar processors, highly parallel processors, artificial intelligence (AI) processors, inference engines, machine-learning processors, other multithreaded processing units, scalar processors, serial processors, programmable logic devices (e.g., field-programmable logic devices (FPGAs)), or any combination thereof. To execute instructions indicating tensor operations to be performed, AU 110 implements one or more processor cores 112 that execute instructions concurrently or in parallel. In some implementations, one or more of the processor cores 112 operate as one or more compute units that each include one or more SIMD units configured to perform matrix multiplication operations. As an example, a SIMD unit includes ALU circuitry configured to perform matrix multiplication operations or tensor operations using data (e.g., values 185) read out of registers 173 (e.g., vector registers) included in or otherwise connected to the processor core 112 that includes the SIMD unit. Though the example implementation presented in FIG. 1 shows AU 110 as including three cores (112-1, 112-2, 112-N) representing an N integer number of cores, in other implementations, AU 110 can include any non-zero integer number of processor cores, each configured to operate as one or more compute units.

Further, processing system 100 includes or otherwise has access to memory 106 that stores program code 105 that, when executed, implements one or more machine-learning models 108 for an application. That is to say, memory 106 is configured to store data representing the machine-learning models 108. In some implementations, memory 106 is implemented using a non-transitory computer-readable medium, for example, a dynamic random-access memory (DRAM), while in other implementations, memory 106 is implemented using other types of memory, including, for example, static random-access memory (SRAM), nonvolatile RAM, and the like. Additionally, memory 106, according to some implementations, includes a memory implemented external to the processing units implemented in the processing system 100. In implementations, program code 105 includes, for example, compiled code (e.g., compiled binary code) indicating instructions that, when executed, cause tensor operations to be performed for an application (e.g., a machine-learning model 108 implemented for an application). As an example, program code 105 includes instructions that indicate dot product operations and other tensor operations to be performed using values 185 for a respective machine-learning model 108.

To improve the accuracy of an implemented machine-learning model 108, AU 110 is configured to perform certain tensor operations (e.g., dot product operations to produce result matrices) for a machine-learning model 108 using values 185 stored (e.g., in a register 173 of the AU 110) in a high-precision data format such as FP64 or FP32 (e.g., FP32 E8M23). As an example, AU 110 is configured to perform one or more certain tensor operations using values 185 in a FP32 data format having an E3M 2 (e.g., 3 exponent bits, 2 mantissa bits) data format style. In implementations, values 185 stored in this high-precision data format are stored in memory 106, a register 173 of AU 110 (e.g., a vector register of a compute unit), or both, and this high-precision data format is represented in FIG. 1 as a first data format 125. However, to reduce the processing resources needed to perform other tensor operations, AU 110 is configured to perform these other tensor operations in a second, lower precision data format, represented in FIG. 1 as modified data format 143. This modified data format 143, to which a value 185 is to be converted, includes one or more lower-precision data formats (e.g., lower precision than the first data format 125) in one or more data format styles. As an example, the modified data format 143 to which a value 185 is to be converted includes FP6 E3M2, FP6 E2M3, FP4 E2M1, and the like. Further, AU 110 is configured to convert a value 185 to a modified data format 143 such that the value 185 is rounded according to a desired rounding mode (e.g., modified rounding mode 141) and so that only a single rounding error is introduced to the value 185 (e.g., the value 185 in the modified data format 143 includes only a single rounding error after being converted from the first data format 125). This desired rounding mode includes, for example, an RNE mode, RTO mode, or stochastic rounding mode, to name a few.

To convert a value 185 to a converted value 103 with a single rounding error (e.g., to convert a value 185 in a first data format 125 to a modified data format 143 in a desired data format style such that the value is rounded according to a modified rounding mode 141 with a single rounding error), AU 110 includes conversion circuitry 114 configured to first convert the value 185 from the first data format 125 to a predetermined intermediate data format 113 (e.g., FP8) in a data format style 123 that allows conversion circuitry 114 to convert the value in the intermediate data format 113 to a desired modified data format 143 in a desired data style format. Further, conversion circuitry 114 rounds the converted value in the intermediate data format 113 according to a rounding mode (e.g., intermediate rounding mode) that allows conversion circuitry 114 to convert the value in the intermediate data format 113 to the modified data format 143 such that the value is rounded according to a desired rounding mode. After rounding the value in the intermediate data format 113 and producing an intermediate value 195, conversion circuitry 114 converts the intermediate value 195 to the modified data format 143 in a desired data format style to produce a converted value 103, which AU 110 then rounds according to the modified rounding mode 141. After producing the converted value 103, AU 110 uses the converted value 103 to perform one or more tensor operations. To enable conversion circuitry 114 to convert a value 185 in a first data format 125 to a modified data format 143 by first converting the value 185 to an intermediate data format 113, AU 110 supports (e.g., includes an instruction set architecture configured to execute) an instruction set 155 including a first instruction group 165 (e.g., convert to intermediate format instruction group) having instructions that, when executed, cause AU 110 to convert a value 185 in a first data format to an intermediate value 195. For example, the first instruction group 165 includes respective instructions that convert values in first data format 125 (e.g., FP32 E8M23) to the predetermined intermediate data format 113 (e.g., FP8) in one or more corresponding intermediate data format styles 123 (e.g., FP8 E5M2, FP8 E4M3) and then round values (e.g., the converted values) based on corresponding intermediate rounding modes 133 (e.g., RNE, RTO, stochastic rounding).

In an example embodiment, the first instruction group 165 includes a first instruction that converts a value 185 from the first data format 125 (e.g., FP32 E8M23) to the predetermined intermediate data format 113 (e.g., FP8) in a first data format style (e.g., E5M2) and rounds the converted value based on a first intermediate rounding mode (e.g., a stochastic rounding process); a second instruction that converts a value 185 from the first data format 125 to the predetermined intermediate data format 113 in the first data format style and rounds the converted value based on a second intermediate rounding mode (e.g., a RNE process); a third instruction that converts a value 185 from the first data format 125 to the predetermined intermediate data format 113 in a second data format style (e.g., E4M3) and rounds the converted value based on the first intermediate rounding mode; a fourth instruction that converts a value 185 from the first data format 125 to the predetermined intermediate data format 113 in the second data format style and rounds the converted value based on the second intermediate rounding mode; and a fifth instruction that converts a value 185 from the first data format 125 to the predetermined intermediate data format 113 in the first data format style and rounds the converted value based on a third intermediate rounding mode (e.g., a RTO rounding process).

Additionally, instruction set 155 includes a second instruction group 175 (e.g., convert from intermediate data format instruction group) having instructions that, when executed, cause AU 110 to convert an intermediate value 195 to a converted value 103 in one or more corresponding modified data formats 143 and rounded according to one or more corresponding modified rounding modes 141. As an example, the second instruction group 175 includes respective instructions that convert an intermediate value 195 in one or more intermediate data format styles (e.g., FP8 E5M2, E4M3) to one or more modified data formats (e.g., FP4, FP6) in one or more corresponding modified data format styles (e.g., FP4 E2M1, FP6 E2M3, FP6 E3M2) and rounds the value according to one or more corresponding modified rounding modes (e.g., SR, RNE). In embodiments, for example, the second instruction group 175 includes a first instruction that converts an intermediate value 195 in a first data format style (e.g., FP8 E5M2) to a first modified data format (e.g., FP6) in a second data format style (e.g., FP6 E3M2) and rounded according to a desired modified rounding mode (e.g., SR, RNE); a second instruction that converts an intermediate value 195 in a third data format style (e.g., FP8 E5M2) to the first modified data format in a fourth data format style (e.g., FP6 E2M3) and rounded according to a desired modified rounding mode; a third instruction that converts an intermediate value 195 in the first data format style to the second modified data format (e.g., FP4) in a fifth data format style (e.g., E2M1) and rounded according to a desired modified rounding mode; and a fourth instruction that converts an intermediate value 195 in the third data format style to the second modified data format in a fifth data format style and rounded according to a desired modified rounding mode.

According to embodiments, processing system 100 includes CPU 102 configured to provide an instruction stream indicating tensor operations to be performed to AU 110. As an example, in implementations, CPU 102 is configured to maintain a command queue (e.g., a circular queue) that stores a set of instructions indicating one or more matrix multiplication operations and tensor operations. After the command queue is ready to be consumed, AU 110 retrieves the set of instructions for the command queue, which forms the instruction stream provided to AU 110. To maintain this command queue, CPU 102 includes one or more processor cores 104 that implement a plurality of processor cores 104-1 to 104-M configured to execute instructions concurrently or in parallel. Though in the example implementation illustrated in FIG. 1, three processor cores (104-1, 104-2, 104-M) are presented representing an M integer number of cores, the number of processor cores 104 implemented in the CPU 102 is a matter of design choice. As such, in other implementations, the CPU 102 can include any non-zero integer number of processor cores 104. In some implementations, to enable communication between CPU 102 and one or more other components (e.g., AU 110, memory 106) of processing system 100, processing system 100 includes input/output (I/O) circuit 118. I/O circuit 118 includes, for example, one or more buses, memory controllers, switches (e.g., PCI switches), data fabrics, queues, buffers, and the like. As an example, I/O circuit 118 is configured to connect a command processor of AU 110 to one or more processor cores 104 of CPU 102, memory 106, or both.

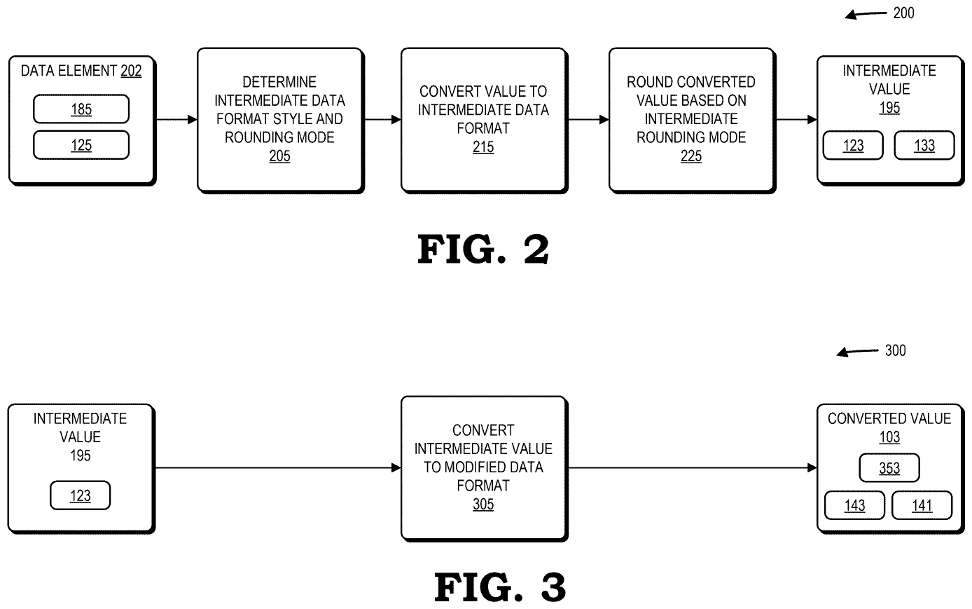

Referring now to FIG. 2, an example operation 200 for converting a value of a data element from a first data format to an intermediate data format is presented, in accordance with embodiments. In embodiments, example operation 200 is implemented at least in part by AU 110 (e.g., by conversion circuitry 114) to convert a value 185 in a first data format 125 (e.g., FP32) to an intermediate value 195 in the intermediate data format 113. Example operation 200 includes, at block 205, AU 110 receiving one or more instructions to convert the value 185 of a data element 202 (e.g., the data element of a weight matrix) from a first data format 125 (e.g., FP32) to a modified data format 143 having a desired data format (e.g., modified data format 123) and a desired rounding mode (e.g., modified rounding mode 141). In response to receiving these instructions, AU 110 determines an intermediate data format style 123 and intermediate rounding mode 133 for the intermediate data format 113 that allows the value 185 of the data element 202 in the intermediate data format 113 to be converted to the modified data format 143 in the desired data format style and desired rounding mode. According to embodiments, AU 110 is configured to identify the intermediate data format style 123 and intermediate rounding mode 133 for the value 185 of the data element 202 based on an instruction received by AU 110 (e.g., an instruction from the first instruction group 165 indicating the intermediate data format style 123, intermediate rounding mode 133, or both), the modified data format 143 indicated by one or more instructions, the desired data format for the modified data format 143, a modified rounding mode 141 for the modified data format 143, or any combination thereof.

After determining the intermediate data format style 123, intermediate rounding mode 133, or both for the value 185 of the data element 202, at block 215, AU 110 converts the value 185 from the first data format 125 to the predetermined intermediate data format 113 (e.g., FP8) in the determined intermediate data format style 123. In embodiments, as an example, at block 215, AU 110 converts the value 185 to the intermediate data format 113 by executing an instruction from the first instruction group 165. AU 110 then, at block 225, rounds the converted value (e.g., the value 185 in the intermediate data format 113 having the intermediate data format style 123) based on the intermediate rounding mode 133. As an example, AU 110 performs one or more rounding operations associated with the intermediate rounding mode 133, such as an RNE operation, RTO operation (e.g., round to odd operation), stochastic rounding operation, or any combination thereof, to round the converted value. After rounding the converted value according to the intermediate rounding mode 133, AU 110 produces an intermediate value 195 in the intermediate data format style 123.

Referring now to FIG. 3, an example operation 300 for converting the value of a data element from an intermediate data format to a modified data format is presented, in accordance with embodiments. In embodiments, example operation 300 is implemented at least in part by AU 110 (e.g., by conversion circuitry 114) to convert a value in the intermediate data format 113 (e.g., FP8) to a modified data format 143 having a desired data format style (e.g., modified data format style 353). Example operation 300, for example, is performed by AU 110 after performing example operation 200 in response to AU 110 receiving one or more instructions to convert the value 185 of a data element 202 from a first data format 125 to the modified data format 143. At block 305 of example operation 300, AU 110 converts an intermediate value 195 (e.g., as rounded by an intermediate rounding format 133) in the intermediate data format 113 having an intermediate data format style 123 to a modified data format 143 having a modified data format style 353 (e.g., FP6 E3M2, FP6 E2M3, FP4 E2M1) and rounds the value according to a modified rounding mode 141 (e.g., SR, RNE). As an example, at block 305, AU 110 executes an instruction from the second instruction group 175 that converts values in the intermediate data format 113 having the intermediate data format style 123 to the modified data format 143 having the modified data format style 353 and rounds the value according to a modified rounding mode 141. After executing this instruction and converting the value to the modified data format 143 having the modified data format style 353, and rounding the value based on the modified rounding mode 141, AU 110 produces a converted value 103 having a single rounding error, which AU 110 then uses to perform one or more tensor operations.

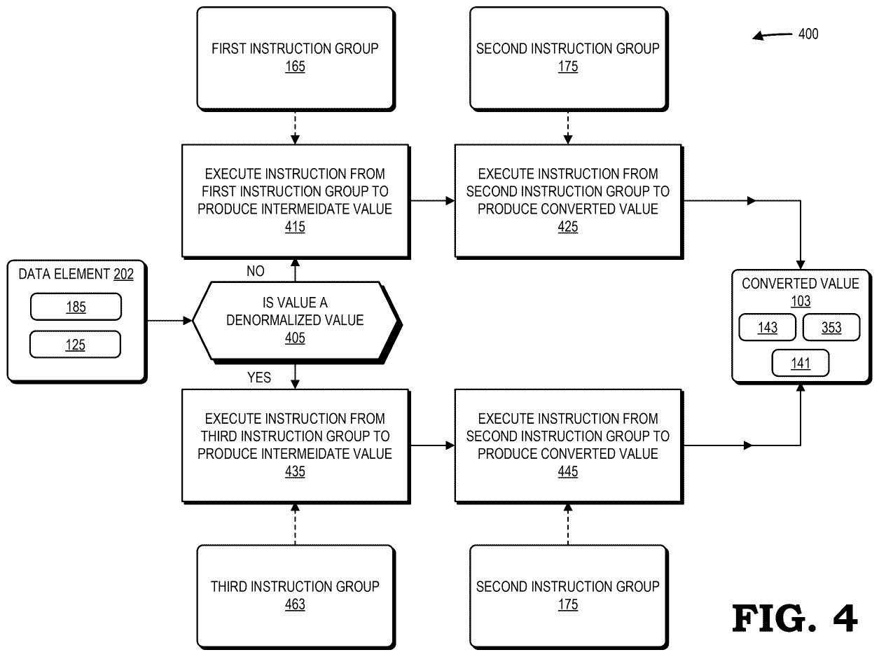

Referring now to FIG. 4, an example operation 400 for converting a value from a first data format to a second, less precise data format based on whether the value is denormalized is presented, in accordance with embodiments. In embodiments, example operation 400 is implemented at least in part by AU 110 (e.g., conversion circuitry 114) in response to AU 110 receiving one or more instructions to convert a value 185 of a data element 202 from a first data format 125 (e.g., FP32) to a modified data format 143 having a desired data format style (e.g., modified data format style 235) and rounded according to a desired rounding mode (e.g., modified rounding mode 141). For example, in response to receiving one or more instructions to convert a value 185 of a data element 202 from a first data format 125 to a modified data format 143 having a modified data format style 353 and rounded according to a modified rounding mode 141, at block 405, AU 110 determines whether the value 185 is a normalized value (e.g., a number having a most significant mantissa bit of one) or a denormalized value (e.g., a number having a most significant mantissa bit of zero).

In response to the value 185 to be converted being a normalized value, at block 415, AU 110 executes an instruction from the first instruction group 165 (e.g., first group of instructions) that converts the normalized value from the first data format 125 to the intermediate data format 113 in an intermediate data format style 123 and rounds the value (e.g., the converted value) according to an intermediate rounding mode 133 that allows the normalized value in the intermediate data format 113 to be converted to the modified data format 143 in the modified data format style 353 such that the value includes only a single rounding error after being rounded according to the modified rounding mode 141. As an example, AU 110 determines an intermediate data format style 123, intermediate rounding mode 133, or both for the normalized value based on one or more received instructions, the desired modified data format 143, the desired modified data format style 353, a desired rounding mode, or any combination thereof. AU 110 then executes an instruction from the first instruction group 165 that converts the normalized value from the first data format 125 to the intermediate data format 113 having the determined intermediate data format style 123 and rounds the converted normalized value according to the determined intermediate rounding mode (e.g., performs one or more rounding operations associated with the determined intermediate rounding mode). After rounding the converted normalized value and, for example, producing an intermediate value 195, at block 425, AU 110 executes an instruction from the second instruction group 175 that converts the normalized value in the intermediate data format 113 having the intermediate data format style 123 to the modified data format 143 having the modified data format style 353 and rounds to value according to a modified rounding mode 141. After executing the instruction from the second instruction group 175, AU 110 produces a converted value 103 in the modified data format 143 that has the modified data format style 353 such that the converted value 103 was rounded according to the modified rounding mode 141 and only a single rounding error was introduced.

Referring again to block 405, in response to the value 185 to be converted being a denormalized value, at block 435, AU 110 executes an instruction from a third instruction group 463 (e.g., third group of instructions) that converts the denormalized value from the first data format 125 to the intermediate data format 113 in an intermediate data format style 123 and rounds the denormalized value according to an intermediate rounding mode 133 that allows the denormalized value in the intermediate data format 113 to be converted to the modified data format 143 in the modified data format style 353 such that the denormalized value includes only a single rounding error after being rounding according to the modified rounding mode 141. This third instruction group 463 includes respective instructions that convert a denormalized value in a first data format 125 to the predetermined intermediate data format 113 in one or more corresponding intermediate data format styles 123 (e.g., FP8 E5M2, FP8 E4M3) and then round denormalized values (e.g., converted denormalized values) based on one or more corresponding intermediate rounding modes 133 (e.g., RNE, RTO, stochastic rounding). This third instruction group 463 includes, as an example, a first instruction that converts a denormalized value from the first data format 125 (e.g., FP32 E8M23) to the predetermined intermediate data format 113 (e.g., FP8) in a first data format style (e.g., E5M2) and rounds the converted denormalized value based on a first intermediate rounding mode (e.g., a stochastic rounding process); a second instruction that converts a denormalized value from the first data format 125 to the predetermined intermediate data format 113 in the first data format style and rounds the converted denormalized value based on a second intermediate rounding mode (e.g., a RNE process); a third instruction that converts a denormalized value from the first data format 125 to the predetermined intermediate data format 113 in a second data format style (e.g., E4M3) and rounds the converted denormalized value based on the first intermediate rounding mode; a fourth instruction that converts a denormalized value from the first data format 125 to the predetermined intermediate data format 113 in the second data format style and rounds the converted denormalized value based on the second intermediate rounding mode; and a fifth instruction that converts a denormalized value from the first data format 125 to the predetermined intermediate data format 113 in the first data format style and rounds the converted value based on a third intermediate rounding mode (e.g., RTO rounding process).

To convert a denormalized value to the intermediate data format 113, according to some embodiments, AU 110 identifies an intermediate data format style 123, intermediate rounding mode 133, or both for the denormalized value based on one or more received instructions, the desired modified data format 143, the desired modified data format style 353, a desired modified rounding mode 141, or any combination thereof for the denormalized value. AU 110 then executes an instruction from the third instruction group 463 that converts the denormalized value from the first data format 125 to the intermediate data format 113 having the determined intermediate data format style 123 and rounds the converted normalized value according to the determined intermediate rounding mode. After rounding the converted denormalized value and, for example, producing an intermediate value 195, at block 445, AU 110 executes an instruction from the second instruction group 175 that converts the denormalized value in the intermediate data format 113 having the intermediate data format style 123 to the modified data format 143 having the modified data format style 353 and rounds the value according to the modified data format 143. After executing the instruction from the second instruction group 175, AU 110 produces a converted value 103 in the modified data format 143 that has the modified data format style 353 such that the converted value 103 includes only a single rounding error.

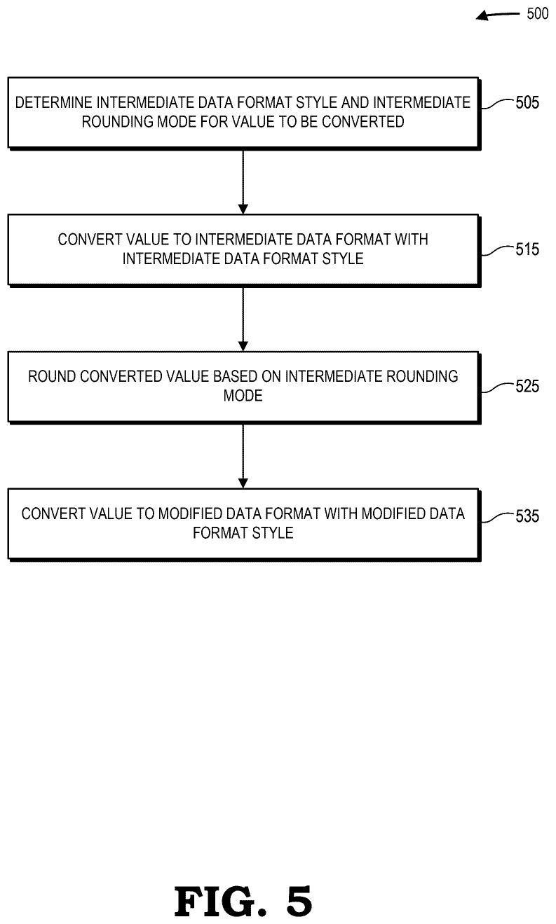

Referring now to FIG. 5, an example method 500 for converting a value from a first data format to a second, less precise data format using an intermediate data format is presented, in accordance with embodiments. In embodiments, example method 500 is implemented at least in part by AU 110 in response to receiving one or more instructions to convert a value 185 from a first data format 125 to a modified data format 143 in a modified data format style 353 and rounded according to a modified rounding mode 141. Example method 500 includes, at block 505, AU 110 determining an intermediate data format style 123 that allows the value 185 in the intermediate data format 113 to be converted to the modified data format 143 having the modified data format style 353 and an intermediate rounding mode 133 that allows the value 185, when converted to the modified data format 143 from the intermediate data format 113, to be rounded according to a desired modified rounding mode 141 such that a single rounding error is introduced. As an example, AU 110 determines an intermediate data format style 123 and an intermediate rounding mode 133 based on one or more received instructions (e.g., one or more instructions from the first instruction group 165), the modified data format 143 to which the value 185 is to be converted, a modified data format style 353 for the modified data format 143, a desired modified rounding mode 141 for the value 185, or any combination thereof, to name a few. After determining an intermediate data format style 123, intermediate rounding mode 133, or both for the intermediate data format 113, at block 515, AU 110 converts the value 185 from the first data format 125 to the intermediate data format 113 having the intermediate data style format 123. As an example, AU 110 executes an instruction from the first instruction group 165 that converts the value 185 to the intermediate data format 113 having the intermediate data format style 123 and then rounds the converted value using a rounding operation indicated by an intermediate rounding mode 133.

After converting the value 185 to the intermediate data format 113 having the intermediate data format style 123, at block 525, AU 110 rounds the converted value based on the determined intermediate rounding mode 133 to produce an intermediate value 195. For example, AU 110 performs one or more rounding operations (e.g., RNE operation, RTO operation, stochastic rounding operation) associated with the intermediate rounding mode 133. AU 110 then, at block 535, converts the intermediate value 195 from the intermediate data format 113 having the intermediate data format style 123 to the modified data format 143 having the modified data format style 353 indicated by one or more instructions received by AU 110. For example, AU 110 executes an instruction from the second instruction group 175 to convert the intermediate value 195 from the intermediate data format 113 having the intermediate data format style 123 to the modified data format 143 having the modified data format style 353 and rounds the value according to the modified rounding mode 141 such that a single rounding error is introduced. According to embodiments, after executing this instruction from the second instruction group 175, AU 110 produces a converted value 103 in the modified data format 143 that AU 110 uses to perform one or more tensor operations for one or more machine-learning models 108.

In some embodiments, the apparatus and techniques described above are implemented in a system including one or more integrated circuit (IC) devices (also referred to as integrated circuit packages or microchips), such as the AU described above with reference to FIGS. 1-5. Electronic design automation (EDA) and computer-aided design (CAD) software tools may be used in the design and fabrication of these IC devices. These design tools are typically represented as one or more software programs. One or more software programs include code executable by a computer system to manipulate the computer system to operate on code representative of circuitry of one or more IC devices so as to perform at least a portion of a process to design or adapt a manufacturing system to fabricate the circuitry. This code can include instructions, data, or a combination of instructions and data. The software instructions representing a design tool or fabrication tool are typically stored in a computer-readable storage medium accessible to the computing system. Likewise, the code representative of one or more phases of the design or fabrication of an IC device may be stored in and accessed from the same computer-readable storage medium or a different computer-readable storage medium.

A computer-readable storage medium may include any non-transitory storage medium, or a combination of non-transitory storage media, accessible by a computer system during use to provide instructions and/or data to the computer system. Such storage media can include, but is not limited to, optical media (e.g., compact disc (CD), digital versatile disc (DVD), Blu-Ray disc), magnetic media (e.g., floppy disc, magnetic tape, or magnetic hard drive), volatile memory (e.g., random access memory (RAM) or cache), non-volatile memory (e.g., read-only memory (ROM) or Flash memory), or microelectromechanical systems (MEMS)-based storage media. The computer readable storage medium may be embedded in the computing system (e.g., system RAM or ROM), fixedly attached to the computing system (e.g., a magnetic hard drive), removably attached to the computing system (e.g., an optical disc or Universal Serial Bus (USB)-based Flash memory), or coupled to the computer system via a wired or wireless network (e.g., network accessible storage (NAS)).

In some embodiments, certain aspects of the techniques described above may be implemented by one or more processors of a processing system executing software. The software includes one or more sets of executable instructions stored or otherwise tangibly embodied on a non-transitory computer-readable storage medium. The software can include the instructions and certain data that, when executed by the one or more processors, manipulate the one or more processors to perform one or more aspects of the techniques described above. The non-transitory computer-readable storage medium can include, for example, a magnetic or optical disk storage device, solid-state storage devices such as Flash memory, a cache, random access memory (RAM), or other non-volatile memory device or devices, and the like. The executable instructions stored on the non-transitory computer-readable storage medium may be in source code, assembly language code, object code, or other instruction format that is interpreted or otherwise executable by one or more processors.

Note that not all of the activities or elements described above in the general description are required, that a portion of a specific activity or device may not be required, and that one or more further activities may be performed, or elements included, in addition to those described. Still further, the order in which activities are listed are not necessarily the order in which they are performed. Also, the concepts have been described with reference to specific embodiments. However, one of ordinary skill in the art appreciates that various modifications and changes can be made without departing from the scope of the present disclosure as set forth in the claims below. Accordingly, the specification and figures are to be regarded in an illustrative rather than a restrictive sense, and all such modifications are intended to be included within the scope of the present disclosure.

Benefits, other advantages, and solutions to problems have been described above with regard to specific embodiments. However, the benefits, advantages, solutions to problems, and any feature(s) that may cause any benefit, advantage, or solution to occur or become more pronounced are not to be construed as a critical, required, or essential feature of any or all the claims. Moreover, the particular embodiments disclosed above are illustrative only, as the disclosed subject matter may be modified and practiced in different but equivalent manners apparent to those skilled in the art having the benefit of the teachings herein. No limitations are intended to the details of construction or design herein shown, other than as described in the claims below. It is therefore evident that the particular embodiments disclosed above may be altered or modified, and all such variations are considered within the scope of the disclosed subject matter. Accordingly, the protection sought herein is as set forth in the claims below.

What is claimed is:

1. A system, comprising:
an accelerator unit (AU), the AU configured to:
in response to receiving one or more instructions to convert a value from a first data format to a second data format in a first data format style, convert the value to the second data format in the first data format style by:
converting the value from the first data format to an intermediate data format in an intermediate data format style; and
converting the value from the intermediate data format in the intermediate data format style to the second data format in the first data format style; and
perform one or more tensor operations using the value in the second data format in the first data format style.

2. The system of claim 1, wherein the AU is configured to convert the value from the first data format to the second data format in the first data format style such that a single rounding error is introduced.

3. The system of claim 1, wherein the AU is configured to:
support a first group of instructions, the first group of instructions including instructions that:
convert values from the first data format to the intermediate data format in corresponding intermediate data format styles; and
round values in the intermediate data format based on corresponding intermediate rounding modes.

4. The system of claim 3, wherein the AU is configured to:
support a second group of instructions, the second group of instructions including instructions that:
convert values from the intermediate data format in corresponding intermediate data format styles to corresponding modified data formats in corresponding modified data format styles.

5. The system of claim 4, wherein the AU is configured to:
in response to the value being a denormalized value, execute an instruction from a third group of instructions supported by the AU, the third group of instructions including instructions that:
convert denormalized values from the first data format to the intermediate data format in corresponding intermediate data format styles; and
round denormalized values in the intermediate data format based on corresponding intermediate rounding modes.

6. The system of claim 1, wherein the second data format has a lower precision than the first data format.

7. The system of claim 1, further comprising a memory configured to store the value in the first data format.

8. A method, comprising:
in response to receiving one or more instructions to convert a value stored in a first data format to a second data format in a first data format style, converting, by an accelerator unit, the value to the second data format in the first data format style by:
converting the value from the first data format to an intermediate data format in an intermediate data format style; and
converting the value from the intermediate data format in the intermediate data format style to the second data format in the first data format style; and
performing, by the AU, one or more tensor operations using the value in the second data format in the first data format style.

9. The method of claim 8, wherein converting the value from the first data format to the second data format in the first data format style introduces a single rounding error.

10. The method of claim 8, further comprising:
supporting, by the AU, a first group of instructions, the first group of instructions including instructions that:
convert values from the first data format to the intermediate data format in corresponding intermediate data format styles; and
round values in the intermediate data format based on corresponding intermediate rounding modes.

11. The method of claim 10, further comprising:
supporting, by the AU, a second group of instructions, the second group of instructions including instructions that:
convert values from the intermediate data format in corresponding intermediate data format styles to corresponding modified data formats in corresponding modified data format styles.

12. The method of claim 10, further comprising:
in response to the value being a denormalized value, executing, by the AU, an instruction from a third group of instructions supported by the AU, the third group of instructions including instructions that:
convert denormalized values from the first data format to the intermediate data format in corresponding intermediate data format styles; and
round denormalized values in the intermediate data format based on corresponding intermediate rounding modes.

13. The method of claim 8, wherein the second data format has a lower precision than the first data format.

14. The method of claim 8, wherein the first data format style indicates a number of exponent bits and a number of mantissa bits.

15. An accelerator unit (AU), comprising:
one or more registers configured to store a value in a first data format; and
one or more processor cores, the one or more processor cores configured to:
convert the value from the first data format to a second data format in a first data format style by:
converting the value from the first data format to an intermediate data format in an intermediate data format style based on the first data format style;
rounding the value in the intermediate data format in the intermediate data format style according to an intermediate rounding mode; and
converting the value from the intermediate data format in the intermediate data format style to the second data format in the first data format style.

16. The AU of claim 15, wherein the one or more processor cores are configured to convert the value from the first data format to the second data format in the first data format style so that a single rounding error is introduced.

17. The AU of claim 15, wherein the AU is configured to support a first group of instructions, the first group of instructions including instructions that:
convert values from the first data format to the intermediate data format in corresponding intermediate data format styles; and
round values in the intermediate data format based on corresponding intermediate rounding modes.

18. The AU of claim 17, wherein the AU is configured to support a second group of instructions, the second group of instructions including instructions that:
convert values from the intermediate data format in corresponding intermediate data format styles to corresponding modified data formats in corresponding modified data format styles.

19. The AU of claim 17, wherein the one or more processor cores are configured to:
in response to the value being a denormalized value, execute an instruction from a third group of instructions supported by the AU, the third group of instructions including instructions that:
convert denormalized values from the first data format to the intermediate data format in corresponding intermediate data format styles; and
round denormalized values in the intermediate data format based on corresponding intermediate rounding modes.

20. The system of claim 1, wherein the second data format has a lower precision than the intermediate data format.
